(19) United States
(12) Patent Application Publication
(10) Pub. No.: US 2010/0091564 A1
(43) Pub. Date: Apr. 15, 2010

(54) MAGNETIC STACK HAVING REDUCED SWITCHING CURRENT

(75) Inventors: Zheng Gao, San Jose, CA (US); Yuankai Zheng, Bloomington, MN (US); Haiwen Xi, Prior Lake, MN (US); Dimitar V. Dimitrov, Edina, MN (US)

Correspondence Address: CAMPBELL NELSON WHIPPS, LLC, HISTORIC HAMM BUILDING, 408 SAINT PETER STREET, SUITE 240, ST. PAUL, MN, 55102, US

(73) Assignee: SEAGATE TECHNOLOGY LLC, Scotts Valley, CA (US)

(21) Appl. No.: 12/425,457

(22) Filed: Apr. 17, 2009

Related U.S. Application Data
(60) Provisional application No. 61/104,395, filed on Oct. 10, 2008.

(51) Int. Cl. G11C 11/14; H01L 29/82; G11C 11/416

(52) U.S. Cl. 365/171; 257/421; 365/189.16; 257/E29.323

(57) ABSTRACT

A magnetic stack having a ferromagnetic free layer, a ferromagnetic pinned reference layer, a non-magnetic spacer layer between the free layer and the reference layer, and a variable layer proximate the free layer. The variable layer is antiferromagnetic at a first temperature and paramagnetic at a second temperature higher than the first temperature. During a writing process, the variable layer is paramagnetic. For magnetic memory cells, such as magnetic tunnel junction cells, the variable layer provides reduced switching currents.

### RELATED APPLICATION

This application claims priority to U.S. provisional patent application No. 61/104,395, filed on Oct. 10, 2008 and titled “Material for Switching Current Reduction”. The entire disclosure of application No. 61/104,395 is incorporated herein by reference.

### BACKGROUND

Fast growth of the pervasive computing and handheld/communication industry has generated exploding demand for high capacity nonvolatile solid-state data storage devices and rotating magnetic data storage devices. Current technology like flash memory has several drawbacks such as slow access speed, limited endurance, and the integration difficulty. Flash memory (NAND or NOR) also faces scaling problems. Also, traditional rotating storage faces challenges in increasing areal density and in making components like reading/recording heads smaller and more reliable.

Resistive sense memories are promising candidates for future nonvolatile and universal memory by storing data bits as either a high or low resistance state. One such memory, magnetic random access memory (MRAM), features non-volatility, fast writing/reading speed, almost unlimited programming endurance and zero standby power. The basic component of MRAM is a magnetic tunneling junction (MTJ). MRAM switches the MTJ resistance by using a current induced magnetic field to switch the magnetization of MTJ. As the MTJ size shrinks, the switching magnetic field amplitude increases and the switching variation becomes more severe.

However, many yield-limiting factors must be overcome before such magnetic stacks can reliable be used as memory devices or field sensors. Therefore, magnetic stacks with decreased switching current and increased thermal stability are desired.

### BRIEF SUMMARY

The present disclosure relates to a magnetic stack, such as a spin torque memory cell, or magnetic tunnel junction cell, that includes a material which is antiferromagnetic at low temperatures and paramagnetic at high temperatures.

In one particular embodiment, this disclosure provides a magnetic stack comprising a ferromagnetic free layer having a switchable magnetization orientation, a ferromagnetic reference layer having a pinned magnetization orientation, a non-magnetic spacer layer between the free layer and the reference layer, and a variable layer proximate the free layer, the variable layer being antiferromagnetic at a first temperature and paramagnetic at a second temperature higher than the first temperature.

In another particular embodiment, this disclosure provides a method for writing a data state to a magnetic tunnel junction that includes a variable layer that is antiferromagnetic at a first temperature and paramagnetic at a second temperature higher than the first temperature. The method includes providing the magnetic tunnel junction at the first temperature, passing a switching current through the magnetic tunnel junction to raise the magnetic tunnel junction to the second temperature, and writing a data state to the magnetic tunnel junction at the second temperature.

These and various other features and advantages will be apparent from a reading of the following detailed description.

### BRIEF DESCRIPTION OF THE DRAWINGS

The disclosure may be more completely understood in consideration of the following detailed description of various embodiments of the disclosure in connection with the accompanying drawings, in which:

FIGS. 1A-1C are cross-sectional schematic diagrams of magnetic stacks, in particular, memory cells;

FIG. 2 is a schematic diagram of an illustrative memory unit including a memory cell and a semiconductor transistor; and

FIG. 3 is a schematic diagram of an illustrative memory array.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

This disclosure is directed to magnetic stacks (e.g., spin torque memory (STRAM) cells and read sensors) that include a material that at low temperature is antiferromagnetic but at high temperature is paramagnetic. By including such a material layer proximate the free layer in a magnetic stack, the thermal stability of the stack can be maintained, and even providing lower switching current in memory cell embodiments.

In the following description, reference is made to the accompanying set of drawings that form a part hereof and in which are shown by way of illustration several specific embodiments. It is to be understood that other embodiments are contemplated and may be made without departing from the scope or spirit of the present disclosure. The following detailed description, therefore, is not to be taken in a limiting sense. Any definitions provided herein are to facilitate understanding of certain terms used frequently herein and are not meant to limit the scope of the present disclosure.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

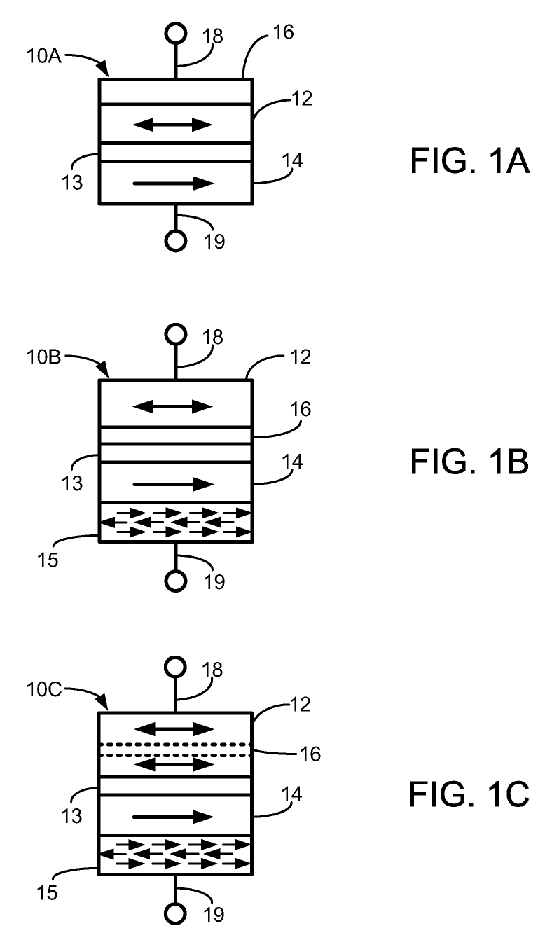

FIG. 1A is a cross-sectional schematic diagram of a magnetic stack element 10A. In some embodiments, magnetic stack element 10A is a magnetic read sensor such as a magnetic read sensor used in a rotating magnetic storage device. In other embodiments, magnetic element 10A is a magnetic memory cell 10A and may be referred to as a magnetic tunnel junction cell (MTJ), variable resistive memory cell or variable resistance memory cell or the like. Magnetic cell 10A includes a ferromagnetic free layer 12 and a ferromagnetic reference (i.e., pinned) layer 14, each having a magnetization orientation. Ferromagnetic free layer 12 and ferromagnetic reference layer 14 are separated by a non-magnetic spacer layer 13. Note that other layers, such as seed or capping layers, are not depicted for clarity.

Ferromagnetic layers 12, 14 may be made of any useful ferromagnetic (FM) material such as, for example, Fe, Co or Ni and alloys thereof, such as NiFe and CoFe, and ternary alloys, such as CoFeB. Either or both of free layer 12 and reference layer 14 may be either a single layer or a synthetic antiferromagnetic (SAF) coupled structure, i.e., two ferromagnetic sublayers separated by a metallic spacer, such as Ru or Cr, with the magnetization orientations of the sublayers in opposite directions to provide a net magnetization. Free layer 12 may be a synthetic ferromagnetic coupled structure, i.e., two ferromagnetic sublayers separated by a metallic spacer, such as Ru or Ta, with the magnetization orientations of the sublayers in parallel directions. Either or both layer 12, 14 are often about 0.1-10 nm thick, depending on the material and the desired resistance and switchability of free layer 12.

Non-magnetic spacer layer 13 is an insulating barrier layer sufficiently thin to allow tunneling of charge carriers between reference layer 14 and free layer 12. Examples of suitable electrically insulating material include oxides material (e.g., Al₂O₃, TiOₓ or MgO). Non-magnetic spacer layer 13 could optionally be patterned with free layer 12 or with reference layer 14, depending on process feasibility and device reliability.

In accordance with this disclosure, magnetic stack or cell 10A includes a variable layer 16 proximate ferromagnetic free layer 12. Variable layer 16 is antiferromagnetic at low temperatures and is paramagnetic at high temperatures. In other words, variable layer 16 has a variable magnetization. In some embodiments, there is no intervening layer between variable layer 16 and free layer 12. Variable layer 16 is often about 0.1-10 nm thick, depending on the material of variable layer 16 and the adjacent free layer 12. In the illustrated embodiment of FIG. 1A, variable layer 16 is positioned so that free layer 12 is between spacer layer 13 and variable layer 16. In an alternate embodiment, illustrated in FIG. 1B, memory cell 10B has variable layer 16 positioned between spacer layer 13 and free layer 12. In yet another embodiment, illustrated in FIG. 1C, memory cell 10C has variable layer 16 present within free layer 12, as an intermediate layer. In some embodiments, variable layer 16 may be a non-continuous and/or non-contiguous layer.

In the embodiment illustrated in FIGS. 1B and 1C, proximate ferromagnetic reference layer 14 is an antiferromagnetic (AFM) pinning layer 15, which pins the magnetization orientation of ferromagnetic reference layer 14 by exchange bias with the antiferromagnetically ordered material of pinning layer 15. Examples of suitable pinning materials include PtMn, IrMn, and others. In alternate embodiments, other mechanisms or elements may be used to pin the magnetization orientation of reference layer 14. Note that other layers, such as seed or capping layers, are not depicted for clarity.

Returning to all of FIGS. 1A, 1B and 1C, in some embodiments, variable layer 16 is a metal, a metal oxide or an alloy. As indicated above, variable layer 16 is antiferromagnetic at a first (i.e., low) temperature and is paramagnetic at a second (i.e., high) temperature. In some embodiments, variable layer 16 is antiferromagnetic at temperatures less than 200° C. and is paramagnetic at temperatures greater than 200° C. In other embodiments, variable layer 16 is antiferromagnetic at temperatures less than 250° C. and is paramagnetic at temperatures greater than 250° C. In still other embodiments, variable layer 16 is antiferromagnetic at temperatures less than 150° C. and is paramagnetic at temperatures greater than 150° C.

Examples of suitable materials for variable layer 16 include Co and Co oxide (CoOₓ), chromium metals and their alloys (e.g., Cr/CrMn, Cr/CrRe, Cr/CrV, and their oxides, and Cr/CrZnO), FeMn oxide (FeMNOₓ), and Ni oxide (NiOₓ). Other metals or metal oxides may additionally have the required properties, of being ferromagnetic at low temperature and paramagnetic at high temperature. Variable layer 16 may be formed of one or more materials, which either individually or together provide the required properties. If variable layer 16 is formed of multiple materials, these materials may be present as domains of one material present in a matrix of another material, or may be stacked layers of materials. For example, variable layer 16 may be a multilayered structure, such as a laminated multilayer structure.

The resistance across magnetic cell 10A, 10B, 10C is determined by the relative orientation of the magnetization vectors or magnetization orientations of ferromagnetic layers 12, 14. The magnetization direction of ferromagnetic reference layer 14 is pinned in a predetermined direction by pinning layer 15 while the magnetization direction of ferromagnetic free layer 12 is free to rotate under the influence of spin torque. During the reading process, which may be with a current of about 10 μA and a temperature less than 100° C. (e.g., about 80° C.), variable layer 16 is antiferromagnetic whereas during the writing process, which is at a much higher temperature (e.g., in some embodiments about 200-250° C.) variable layer 16 is paramagnetic.

To provide current to cell 10A, 10B, 10C, a first electrode 18 is in electrical contact with ferromagnetic free layer 12 and a second electrode 19 is in electrical contact with ferromagnetic reference layer 14 via optional pinning layer 15. Electrodes 18, 19 electrically connect ferromagnetic layers 12, 14 to a control circuit providing read and write currents through layers 12, 14.

In each of FIGS. 1A, 1B, 1C, the magnetization orientation of free layer 12 is illustrated as undefined. In some embodiments, the magnetization orientation of free layer 12 will generally be either parallel to the magnetization orientation of reference layer 14 (i.e., the low resistance state) or anti-parallel to the magnetization orientation of reference layer 14 (i.e., the high resistance state). In some embodiments, the low resistance state may be the “0” data state and the high resistance state the “1” data state, whereas in other embodiments, the low resistance state may be “1” and the high resistance state “0”.

Switching the resistance state and hence the data state of magnetic cell 10A, 10B, 10C via spin-transfer occurs when a current, under the influence of a magnetic layer of magnetic cell 10A, 10B, 10C, becomes spin polarized and imparts a spin torque on free layer 12. When a sufficient level of polarized current and therefore spin torque is applied to free layer 12, the magnetization orientation of free layer 12 can be changed among different directions and accordingly, the magnetic cell can be switched between the parallel state, the anti-parallel state, and other states.

In other embodiments, the magnetization orientation of free layer 12 is influenced by a magnetic field located on a magnetic recording medium. When a sufficient magnetic field is applied to free layer 12, the magnetization orientation of free layer 12 can be changed among different directions, between the parallel state, the anti-parallel state, and other states.

The properties of variable layer 16, being antiferromagnetic at low temperatures and paramagnetic at high temperatures, allow the use of lower switching current (e.g., no more than about 100-500 μA (about 1-5 mA)) while maintaining thermal stability of the magnetization orientations, than if no variable layer was present. In some embodiments, the switching current is no more than 400 μA, in other embodiments no more than about 200 μA. When no switching current is present, variable layer 16 is at a low temperature and is antiferromagnetic. Free layer 12 is stabilized by the adjacent antiferromagnetic material. Because the blocking temperature is low (e.g., about 100° C., or about 150° C.), there is no issue regarding temperature variation from one cell 10A, 10B, 10C to an adjacent cell when applying a switching current to cell 10A, 10B, 10C or to the adjacent cell. The antiferromagnetic material confines thermal dissipation to the cell being written and thus reduces the necessary switching current. When switching current is present for cell 10A, 10B, 10C, variable layer 16 is at a high temperature and is paramagnetic. The paramagnetic variable layer 16 is less stabilizing to free layer 12 than the antiferromagnetic variable layer 16, thus allowing free layer 12 to switch readily. Additionally, the paramagnetic property provides a specular (e.g., reflective) effect within free layer 12, thus reducing the needed switching current for that cell 10A, 10B, 10C. A non-continuous or non-contiguous variable layer 16, whether within free layer 12 or on either side of free layer 12, may further reduce the switching current by focusing the current and increasing the current density.

Switching the resistance state and hence the data state of magnetic tunnel junction memory cell 10A, 10B, 10C via spin-transfer occurs when a current, passing through a magnetic layer, becomes spin polarized and imparts a spin torque on free layer 12. When a sufficient spin torque is applied to free layer 12, the magnetization orientation of free layer 12 can be switched between two opposite directions and accordingly, magnetic tunnel junction memory cell 10A, 10B, 10C can be switched between the low resistance state and the high resistance state.

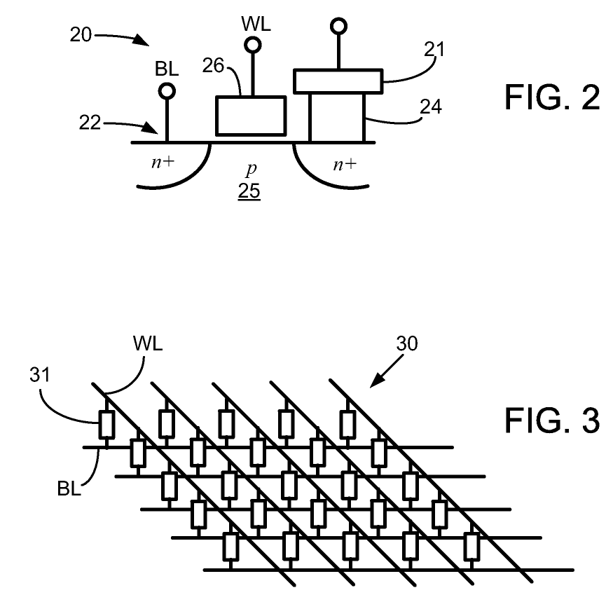

FIG. 2 is a schematic diagram of an illustrative memory unit 20 including a memory element 21 electrically coupled to a semiconductor transistor 22 via an electrically conducting element 24. Memory element 21 may be any of the memory cells described herein, or may be any other memory cell having a variable layer and configured for switching data states via a current passed through memory element 21. Transistor 22 includes a semiconductor substrate 25 having doped regions (e.g., illustrated as n-doped regions) and a channel region (e.g., illustrated as a p-doped channel region) between the doped regions. Transistor 22 includes a gate 26 that is electrically coupled to a word line WL to allow selection and current to flow from a bit line BL to memory element 21. An array of memory units 20 can be formed on a semiconductor substrate utilizing semiconductor fabrication techniques.

FIG. 3 is a schematic diagram of an illustrative memory array 30. Memory array 30 includes a plurality of word lines WL and a plurality of bit lines BL forming a cross-point array. At each cross-point a memory element 31 is electrically coupled to word line WL and bit line BL. Memory element 31 may be any of the memory cells described herein, or may be any other memory cell having a variable layer.

The structures of this disclosure, including any or all of layers 12, 13, 14, 16, may be made by thin film techniques such as chemical vapor deposition (CVD), physical vapor deposition (PVD), and atomic layer deposition (ALD).

Thus, embodiments of the MAGNETIC STACK HAVING REDUCED SWITCHING CURRENT are disclosed. The implementations described above and other implementations are within the scope of the following claims. One skilled in the art will appreciate that the present disclosure can be practiced with embodiments other than those disclosed. The disclosed embodiments are presented for purposes of illustration and not limitation, and the present invention is limited only by the claims that follow.

What is claimed is:

1. A magnetic stack comprising:
a ferromagnetic free layer having a switchable magnetization orientation;
a ferromagnetic reference layer having a pinned magnetization orientation;
a non-magnetic spacer layer between the free layer and the reference layer; and
a variable layer proximate the free layer, the variable layer being antiferromagnetic at a first temperature and paramagnetic at a second temperature higher than the first temperature.

2. The magnetic stack of claim 1 wherein the free layer is between the spacer layer and the variable layer.

3. The magnetic stack of claim 1 wherein the variable layer is between the spacer layer and the free layer.

4. The magnetic stack of claim 1 wherein the variable layer is within the free layer.

5. The magnetic stack of claim 1 wherein the first temperature is less than 250° C. and the second temperature is greater than 250° C.

6. The magnetic stack of claim 1 wherein the first temperature is less than 200° C. and the second temperature is greater than 200° C.

7. The magnetic stack of claim 1 wherein the first temperature is less than 150° C. and the second temperature is greater than 150° C.

8. The magnetic stack of claim 1 wherein the variable layer comprises metal or metal oxide.

9. The magnetic stack of claim 8 wherein the variable layer comprises Co, CoOₓ, Cr, Cr/CrMn, Cr/CrRe, Cr/CrV, Cr/CrZnO, FeMNOₓ, or NiOₓ.

10. The magnetic stack of claim 1 wherein the variable layer is a single layer.

11. The magnetic stack of claim 1 wherein the variable layer is a multilayer laminated structure.

12. The magnetic stack of claim 1 wherein the magnetic stack is a magnetic tunnel junction memory cell.

13. The magnetic stack of claim 1 wherein the magnetic stack is a magnetic read sensor in a recording head.

14. A magnetic tunnel junction comprising:
a ferromagnetic free layer having a switchable magnetization orientation;
a ferromagnetic reference layer having a pinned magnetization orientation;
a non-magnetic spacer layer between the free layer and the reference layer; and
a variable layer proximate the free layer, the variable layer being antiferromagnetic during a reading process of the magnetic tunnel junction and paramagnetic during a writing process of the magnetic tunnel junction.

15. The magnetic tunnel junction of claim 14 wherein the free layer is between the spacer layer and the variable layer.

16. The magnetic tunnel junction of claim 14 wherein the variable layer is between the spacer layer and the free layer.

17. The magnetic tunnel junction of claim 14 wherein the variable layer is within the free layer.

18. The magnetic tunnel junction of claim 14 wherein the reading process is at a temperature less than 200° C. and the writing process is at a temperature greater than 200° C.

19. The magnetic tunnel junction of claim 14 wherein the variable layer comprises Co, CoOₓ, Cr, Cr/CrMn, Cr/CrRe, Cr/CrV, Cr/CrZnO, FeMNOₓ, or NiOₓ.

20. A method for writing a data state to a magnetic tunnel junction having a variable layer proximate a ferromagnetic free layer, the variable layer being antiferromagnetic at a first temperature and paramagnetic at a second temperature higher than the first temperature, the method comprising:
providing the magnetic tunnel junction at the first temperature;
passing a switching current through the magnetic tunnel junction to raise the magnetic tunnel junction to the second temperature; and
writing a data state to the magnetic tunnel junction at the second temperature.

21. The method of claim 20 wherein the switching current is no more than about 500 microAmps.
